(19) United States
(12) Patent Application Publication
(10) Pub. No.: US 2009/0323407 A1
(43) Pub. Date: Dec. 31, 2009

(54) Memory device, an information storage process, a process, and a structured material

(76) Inventors: James Stanislaus Williams, Australian Capital Territory (AU); Jodi Elisabeth Bradby, Australian Capital Territory (AU); Michael Vincent Swain, New South Wales (AU)

Correspondence Address: KNOBBE MARTENS OLSON & BEAR LLP, 2040 MAIN STREET, FOURTEENTH FLOOR, IRVINE, CA, 92614, US

(21) Appl. No.: 10/582,588

(22) PCT Filed: Dec. 9, 2004
(86) PCT No.: PCT/AU04/01735

§ 371 Date: Apr. 24, 2007

(30) Foreign Application Priority Data
Dec. 9, 2003 (AU) 2003906808

(51) Int. Cl. G11C 11/00

(52) U.S. Cl. 365/163; 365/148

(57) ABSTRACT

A memory device, including a plurality of nanoscale memory cells (1510, 1512) created by applying pressure to and removing pressure from one or more regions (1510, 1512) of a substance (1502) to change the electrical conductivity of those regions (1510, 1512). An electrically conductive read probe (1514) determines the conductivities of the regions and thereby the information stored in the cells. A write probe (1508) applies pressure to and removes pressure from selected cells to change the electrical conductivity of those cells and thereby store or erase information.

### FIELD OF THE INVENTION

The present invention relates to a memory device, an information storage process, a process, and a structured material.

### BACKGROUND

The rapid progress in microelectronics is often represented by Moore's Law, which predicts that the number of transistors per integrated circuit will continue to double every couple of years. This doubling requires the physical size of each transistor to decrease with each successive generation of integrated circuits. However, the difficulty of achieving this shrinkage has increased dramatically, to the point where it may not be economically feasible to continue to follow Moore's Law due to exponential increases in complexity and the time required to develop new generations of integrated circuits. On the other hand, the enormous demand for memory chips, as opposed to microprocessors, may justify such high development costs for memory devices. Yet the challenges of developing ever smaller memory devices remains considerable, particularly as the characteristic dimensions of such devices enter the nanometer scale.

Existing random access memory (e.g., SRAM, DRAM) devices store information in an array of memory cells, with each cell storing a single bit of binary data. In a typical memory device, the bit of data stored in a particular cell can be accessed by applying an appropriate potential to the wordline connection to the array row containing the cell and measuring the resulting potential of a bitline connection to the cell. One of the difficulties of existing memory devices is that the ability to reduce the physical dimensions of each cell is limited, placing an upper limit on the density of information storage. For example, in the case of transistor-based memory devices, although the gate length of each transistor is extremely small (typically around 100 nm in current technology), the total surface area or footprint of each cell is at least an order of magnitude larger. There is thus a need for a memory device with a simpler structure that would allow a higher density of cells to be produced.

It is desired, therefore, to provide a memory device, an information storage process, a process, and a structured material that alleviate one or more difficulties of the prior art, or at least provide a useful alternative.

### SUMMARY OF THE INVENTION

In accordance with the present invention, there is provided an information storage process, including applying pressure to and removing pressure from one or more regions of a substance to store information in said one or more regions.

The present invention also provides a process, including applying pressure to and removing pressure from one or more regions of relaxed amorphous silicon to transform said one or more regions into substantially crystalline silicon.

The present invention also provides a process, including applying pressure to and removing pressure from one or more regions of a substance to change at least one property of said one or more regions.

The present invention also provides a process, including applying pressure to and removing pressure from one or more regions of a substance to induce a phase change in at least a portion of each of said one or more regions.

The present invention also provides a process, including applying pressure to and removing pressure from one or more regions of relaxed amorphous silicon to transform at least a portion of each of said one or more regions to at least one crystalline phase.

The present invention also provides a process for producing regions of substantially crystalline and substantially amorphous silicon by applying pressure to and removing pressure from one or more regions of a substantially silicon substrate.

The present invention also provides a process for producing regions having different electrical and/or physical properties by applying pressure to and removing pressure from one or more regions of a substantially silicon substrate.

The present invention also provides a memory device, including a plurality of memory cells created by applying pressure to and removing pressure from one or more regions of a substance to change the electrical conductivity of said one or more regions from a first electrical conductivity to a second electrical conductivity to provide said plurality of memory cells.

The present invention also provides a memory device, including a plurality of substantially conducting regions of crystalline silicon in a layer of substantially insulating relaxed amorphous silicon.

The present invention also provides a memory device, including a plurality of first regions having a first electrical conductivity, a plurality of second regions having a second electrical conductivity, and at least one electrically conductive probe for determining the conductivities of said regions to determine stored information represented by said conductivities.

The present invention also provides a memory device, including a plurality of first regions having a first electrical conductivity as a result of applying pressure to and removing pressure from said first regions, a plurality of second regions having a second electrical conductivity, conductive wordlines adjacent said first regions and said second regions, and conductive bitlines adjacent said first regions and said second regions; wherein the conductivity of a selected one of said first regions and said second regions can be determined by accessing a corresponding wordline and a corresponding bitline.

The present invention also provides a memory device, including a plurality of substantially insulating regions of amorphous silicon in a layer of conducting crystalline silicon, said regions of amorphous silicon formed by applying pressure to and removing pressure from corresponding regions of said layer of conducting crystalline silicon.

The present invention also provides a memory device adapted to store information in memory cells of said device by changing an electrical property of silicon.

The present invention also provides a memory device, including at least one indenter tip for storing and/or erasing information in cells of said device by indentation.

The present invention also provides a structured material, including one or more substantially crystalline regions in a layer of relaxed amorphous silicon.

### BRIEF DESCRIPTION OF THE DRAWINGS

Preferred embodiments of the present invention are hereinafter described, by way of example only, with reference to the accompanying drawings, wherein:

FIG. 1 is a schematic diagram illustrating phase changes that occur during indentation of crystalline silicon (Si-I);

FIG. 2 is a graph of the load applied to crystalline silicon (Si-I) as a function of penetration depth for loading and unloading;

FIG. 3 is a graph of Raman spectroscopy data from pristine Si-I and an indented region;

FIG. 4 is a dark field cross-section transmission electron microscopy (XTEM) image of an indent following indentation of crystalline Si-I;

FIG. 5 is a schematic diagram illustrating the preparation of relaxed amorphous Si;

FIG. 6 is a graph of the load applied to unannealed (unrelaxed) amorphous silicon as a function of penetration depth for loading and unloading;

FIG. 7 is a graph of Raman spectroscopy data from pristine unannealed a-Si and indented regions in unannealed and annealed a-Si;

FIG. 8 is a bright-field XTEM image of an indented region of unrelaxed a-Si;

FIG. 9 is a schematic diagram illustrating the indentation of unrelaxed a-Si;

FIG. 10 is a graph of the load applied to relaxed a-Si as a function of penetration depth for loading and unloading;

FIG. 11 is an XTEM micrograph of an indented region of relaxed a-Si,

FIG. 12 is a schematic diagram illustrating the phases formed during indentation of relaxed a-Si showing how Si-XII/Si-III is formed and subsequently transformed back to the amorphous phase.

FIG. 13 is a graph of the load applied to crystalline silicon (Si-I) as a function of penetration depth for loading and unloading with a tip having a radius of 77 nm;

FIG. 14 is an XTEM image of an indent produced by indentation of relaxed amorphous silicon and subsequent annealing, the latter causing transformed regions within the indent to further transform to Si-I;

FIG. 15 is a schematic diagram of a preferred embodiment of a read-write memory device; and

FIG. 16 is a schematic diagram of a preferred embodiment of a read-only memory device.

### DESCRIPTION OF BACKGROUND PRIOR ART

### Phase Changes in Crystalline Cubic-Silicon (Si-I)

Crystalline cubic-silicon (also referred to as Si-I, the ‘common’ silicon phase produced in wafer form for the manufacture of microelectronic devices) undergoes a series of phase transformations during mechanical deformation. High-pressure diamond anvil experiments have shown that crystalline diamond-cubic Si-I undergoes a phase transformation to a metallic β-Sn phase (also referred to as Si-II) during loading at a pressure of ˜11 GPa, as described in J. Z. Hlu, L. D. Merkle, C. S. Menoni, and I. L. Spain, Phys. Rev. B 34, 4679 (1986), and because Si-II is unstable at pressures below ˜2 GPa, the Si-II undergoes further transformation during pressure release.

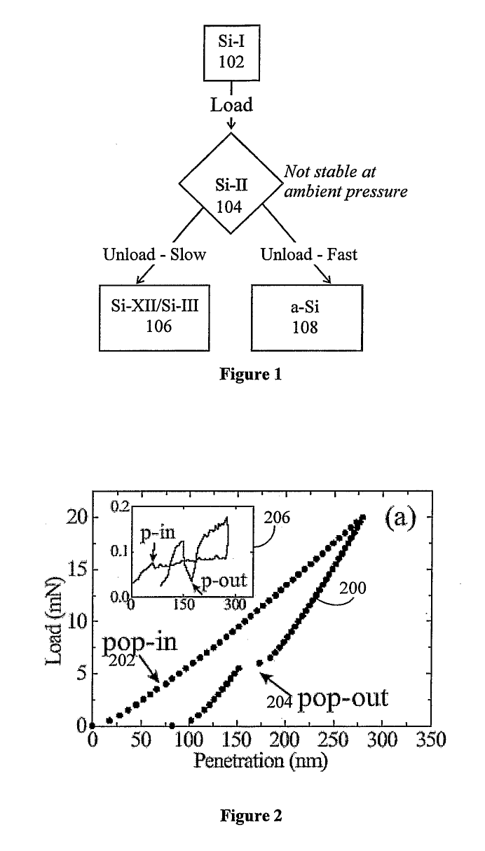

Si-I undergoes a similar series of phase transformations during a process referred to as indentation, wherein an extremely hard indenter tip is pressed into the surface of a material by increasing application of force (referred to as the loading phase), and this force is subsequently decreased (referred to as the unloading phase) and the indenter tip removed from the now deformed or indented surface. FIG. 1 summarises the phase transformations that occur during indentation loading and unloading of Si-I. As in diamond-anvil experiments, the initial Si-I phase 102 transforms to the Si-II phase 104 under pressure; i.e., during loading. On unloading, the Si-II phase 104 undergoes additional transformations to form either the crystalline phases Si-XII/Si-III 106 or an amorphous phase (a-Si) 10S, depending on the unloading speed. Fast unloading leads to the formation of a-Si 108, whereas slow unloading results in the formation of Si-XII/Si-III 106, as shown.

The results of indentation experiments of Si-I, and in particular the subsequent analysis of the indented regions using Raman spectroscopy and cross-sectional transmission electron microscopy (XTEM) are described below.

The indentations were made using an Ultra-Micro-Indentation-System 2000 (UMIS) using one of two spherical indenters of ˜5 μm and ˜2.0 μm radius, at ambient temperature and pressure. Both the UMIS and the indenter tips were carefully calibrated using fused silica, with the radii of the tips also obtained by scanning electron microscopy.

### Indentation of Si-I

Measurements of the force or load applied to the indenter tip and the corresponding penetration depth of the indenter tip below the original surface position during indentation of crystalline Si-I show evidence of the phase Transformations described above. FIG. 2 shows a typical graph of the applied load as a function of penetration depth (also referred to as a load-penetration curve) 200 for Si-I using a spherical indenter tip of ˜2.0 μm radius and a maximum load of 20 mN. Consistent with the previously reported behaviour of Si-I indentation with a spherical indenter tip, this curve 200 shows a ‘pop-in’ event feature 202 during loading, and a ‘pop-out’ event feature 204 during unloading. (The inset 206 to FIG. 2 shows the first derivative of the load versus penetration curve 200, more clearly indicating the position of the pop-in event.) The pop-in event is thought to occur as a result of the Si-I to Si-II phase transformation during loading, and the pop-out event is thought to indicate the Si-II to Si-XII/Si-III phase transformation during unloading. Because Si-II is not stable at ambient pressures, it transforms as the pressure is decreased during unloading. As described in Gogotsi et. al., J. Mat. Res. 871, (2000), load-penetration curves for indentation of Si-I that include a slope change or ‘elbow’ during unloading instead of a pop-out event indicate a Si-II to a-Si phase transformation. Thus strong indications of phase transformations can be found by examining such data. However, to directly detect the phase transformed materials present after indentation, further characterisation techniques are required. Consequently, the indented regions were characterised using Raman spectroscopy and XTEM.

### Raman Spectroscopy Following Indentation of Si-I

Raman spectroscopy is used to determine the presence of different phases of Si, in particular a-Si, Si-I, and Si-XII/Si-III. Raman spectra were recorded with a Renishaw 2000 Raman Imaging Microscope, using the 632.8 nm excitation line of a helium-neon laser. The spectra were taken using a laser beam spot of ˜1.0 μm radius, and the beam intensity was kept low to avoid laser-induced transformations.

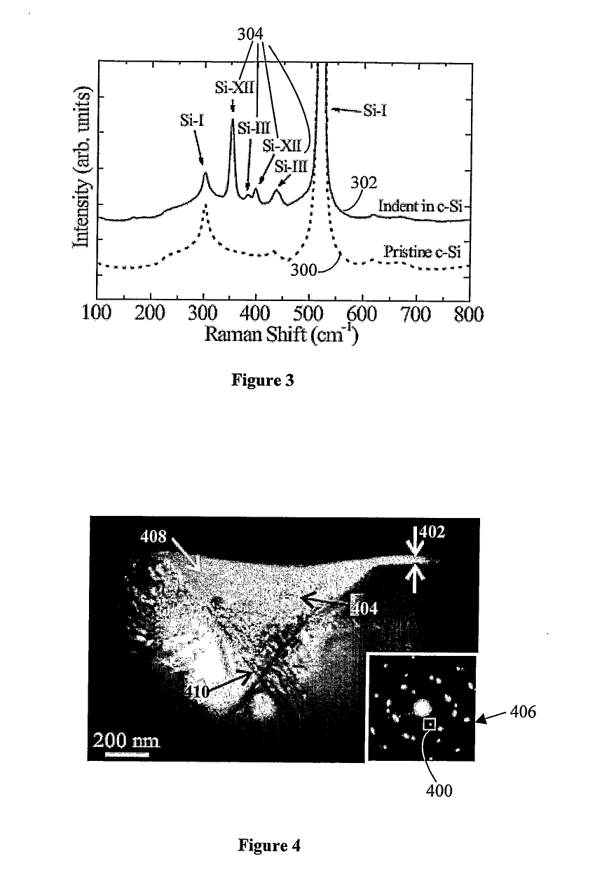

FIG. 3 shows a Raman spectrum 300 from a region of pristine Si-I and a Raman spectrum 302 from an indented region following indentation of Si-I. The spectrum 300 taken from the pristine region shows only the two Raman bands at 520 cm⁻¹ and 300 cm⁻¹. In contrast, the Raman spectrum 302 taken from the indent shows four additional Raman bands 304 which are known to be characteristic of the phases Si-III and Si-XII.

### XTEM Analysis After Indentation of Si-I

XTEM samples of the indented regions were prepared in order to directly image the transformed regions. The samples were prepared using a FEIxP200 focused-ion-beam (FIB) system which uses a focussed beam of Ga ions to accurately sputter away the surrounding material, leaving an electron transparent region of the indent. A Philips CM 300 operating at an accelerating voltage of 300 kV was used to generate the XTEM images.

An XTEM image of the structure resulting from indentation of Si-I with a 2 μm radius spherical indenter to a maximum load force of 20 mN is shown in FIG. 4. The inset shows a selected area diffraction pattern (SADP) 406 of the region immediately beneath the residual indent. A thin layer 402 of amorphous silicon over the whole surface of the sample is caused by the FIB sample preparation process. The dark field XTEM image of FIG. 4 was generated using a Si-III/Si-XII diffraction spot 400, and highlights the polycrystalline high pressure phases 404 in the image. The large number of spots and diffuse rings in the SADP 406 confirms that phase transformed material (both Si-III/Si-XII and a-Si) is present. The a-Si 408 in the transformed region beneath the residual indent can be clearly seen as a grey featureless region. Indents with exclusively a-Si as the final phase (as opposed to a mixture of Si-XII/Si-III and a-Si, as shown in FIG. 4) can be formed by fast unloading.

### Electrical Measurements During Indentation

As described in J. E. Bradby, J. S. Williams, J. Wong-Leung, M. V Swain, and P. Munroe, J. Mat. Res. 16, 1500 (2001), in-situ electrical measurements during indentation of Si-I demonstrate that it is possible to detect the transformation from Si-I to the intermediate metallic Si-II phase on loading, and that on unloading the Si-II undergoes further transformations to form less conducting phases.

Amorphous Silicon (a-Si)

a-Si is an unusual phase in that it appears to exhibit markedly different properties, depending on preparation and annealing conditions. In particular, a-Si can exist in two states: an ‘unrelaxed’ state (e.g., as-deposited or directly after formation by ion-implantation at room temperature), and a ‘relaxed’ state (formed by annealing unrelaxed a-Si at 450° C.), and these two states display a range of property differences. As-implanted (unrelaxed) a-Si has been found to be significantly softer than Si-I, but annealed (relaxed) a-Si has been found to have very similar mechanical properties to those of the crystalline state Si-I. The reason for these differences is not known.

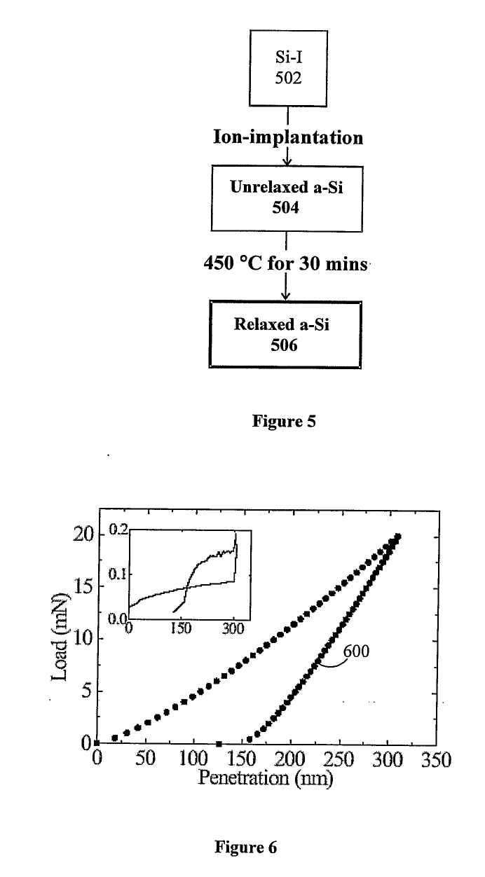

As shown in FIG. 5, a continuous layer of unrelaxed a-Si 504 can be prepared by ion-implantation of crystalline Si-I 502 with 600 keV Si ions at liquid nitrogen temperature using a 1.7 MV tandem accelerator. After implantation, the sample can be annealed for 30 minutes at a temperature of 450° C. in an argon atmosphere to cause the unrelaxed a-Si 504 to transform to ‘relaxed’ a-Si 506. The thicknesses of the relaxed and unrelaxed amorphous layers were both measured to be ˜650 mm by Rutherford backscattering (RBS) with 2 MeV helium ions, demonstrating that the annealing process was not sufficient to recrystallize the a-Si layer, and hence the layer remains amorphous. Thus the two states are both amorphous states of silicon.

### Detailed Description of Preferred Embodiments of the Invention

The preferred embodiments of the present invention are based on the following new findings. In the set of experiments described below, a-Si is used as the starting material to identify any instances of phase transformations occurring during indentation. As described above, fast unloading of Si-If leads to a final phase of a-Si. Thus, in order to detect the formation of crystalline phases, care was taken to avoid fast unloading rates.

Indentation of Unrelaxed a-Si

As shown in FIG. 6, the load-penetration curve 600 for indentation of unrelaxed a-Si is predominantly featureless, and in particular no pop-in or pop-out events are observed, suggesting that no phase transformations are occurring during indentation.

Raman Spectroscopy After Indentation of Unrelaxed a-Si

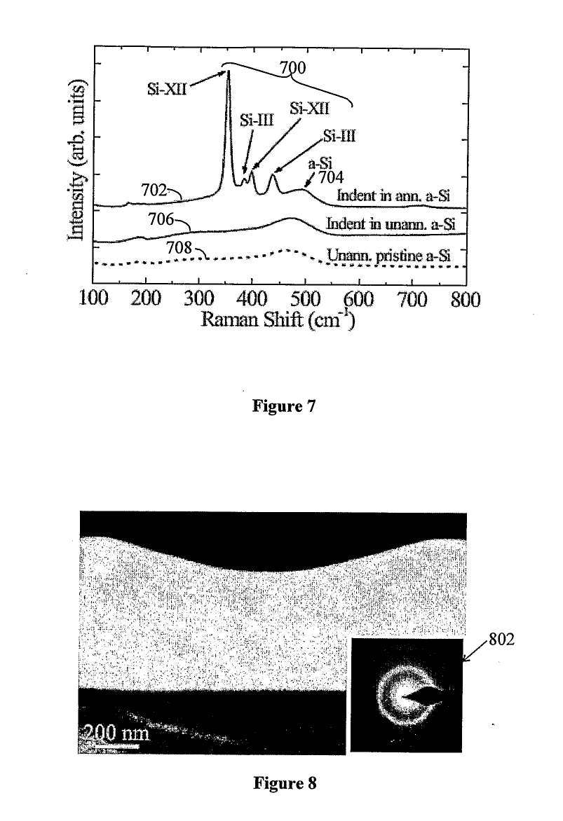

As shown in FIG. 7, the Raman spectrum 706 from an indented region of unrelaxed a-Si appears to be identical to the Raman spectrum 708 from pristine (i.e., not indented) a-Si, including the broad peak associated with a-Si at 480 cm⁻¹. In particular, there are no Raman bands characteristic of crystalline phases.

XTEM After Indentation of Unrelaxed a-Si

FIG. 8 is a XTEM image of an indent in unrelaxed a-Si. The SADP 802 from the region directly below the residual indent impression confirms that no crystalline phases are present, indicating that no phase transformations occur during indentation of unrelaxed a-Si. This observation is also supported by in situ electrical measurements.

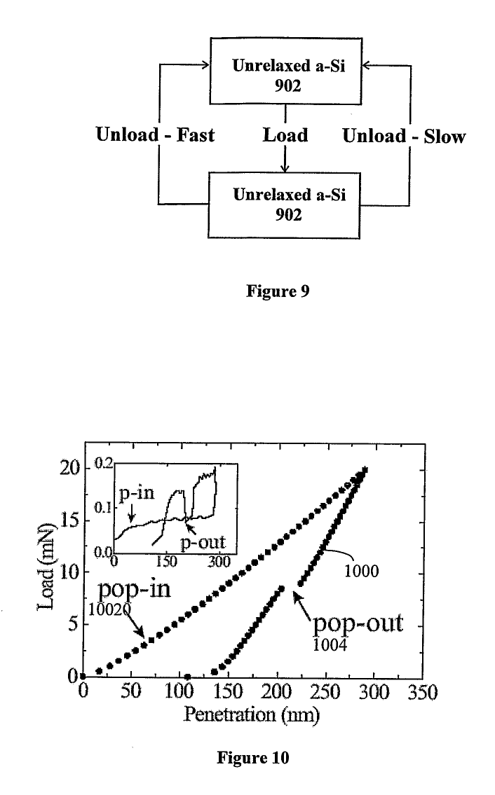

A schematic diagram representing the indentation of unrelaxed a-Si 902 is shown in FIG. 9. Unrelaxed a-Si undergoes simple flow during loading and does not undergo a phase transformation.

Indentation of Relaxed a-Si

As shown in FIG. 10, a load-penetration curve 1000 of relaxed a-Si follows the same trend as the load-penetration curve 200 for a crystalline Si-I sample (as shown in FIG. 2), with a pop-in event 1002 during loading, and a pop-out event 1004 during unloading.

Raman Spectroscopy After Indentation of Relaxed a-Si

As shown in FIG. 7, a Raman spectrum 702 taken from an indent in relaxed a-Si includes four additional Raman bands 700 associated with the Si-XII and Si-III phases. These four additional bands 700 are the same four Raman bands 304 that appear after indentation of Si-I, as shown in FIG. 3. FIG. 7 also shows the broad peak 704 associated with the surrounding a-Si at 480 cm⁻¹. Because Raman spectroscopy is not sensitive to differences between the two states of a-Si, Raman spectra from the pristine relaxed and pristine unrelaxed a-Si appear identical.

XTEM After Indentation of Relaxed a-Si

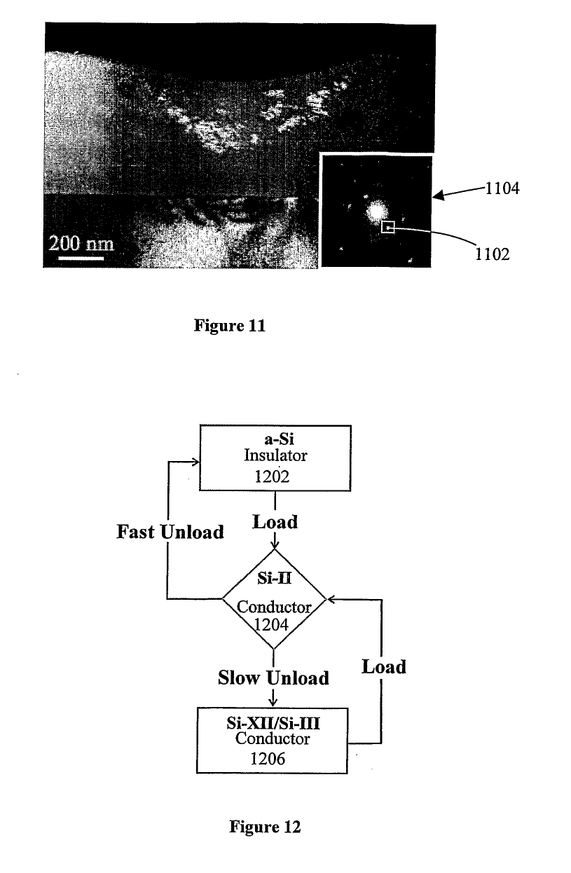

As shown in FIG. 11, XTEM analysis of a residual indent in relaxed a-Si clearly demonstrates that a phase transformation has occurred. The dark field image of FIG. 11 was produced from the boxed diffraction spot 1102 from Si-III/Si-XII shown in the diffraction pattern 1104.

As described above, in contrast to unrelaxed a-Si, relaxed a-Si undergoes phase transformations during indentation loading and unloading. As shown in FIG. 12, on loading, relaxed a-Si 1202 transforms to the metallic Si-II phase 1204. In situ electrical measurements confirm the transformation to an electrically conducting phase. On unloading, the Si-II phase 1204 undergoes further transformations depending on the rate of pressure release. Slow unloading leads to the formation of Si-XII/Si-III 1206, whereas fast unloading leads to the formation of a-Si. It is not clear whether the a-Si formed on unloading is in the relaxed or unrelaxed state but, as is indicated below, this does not appear to influence its ability to transform to Si-II on subsequent reindentation.

Electrical Properties of Si-XII/Si-III Compared to a-Si

In-situ electrical measurements indicate that the silicon phases Si-XII/Si-III are significantly more conducting than a-Si, which is essentially an insulator, whether in a relaxed or unrelaxed state.

### Indentation of Si-XII/Si-III (Re-Indentation)

Re-indentation of an indent containing the pressure-induced phases Si-XII/Si-III and/or a-Si shows that these phases too undergo a phase transformation to Si-II on loading (at about the same critical pressure of ˜11 GPa), and to either Si-XII/Si-III again or a-Si on unloading, depending on the unloading rate. It is believed that a major contributing factor for these phases to transform on re-indentation is that they are confined under the indenter and surrounded by Si-I and/or relaxed a-Si. Under such conditions there are no pathways, other than transformation, for them to relieve the compressive stress imposed by indentation.

### Phase Transformations at the Nanoscale

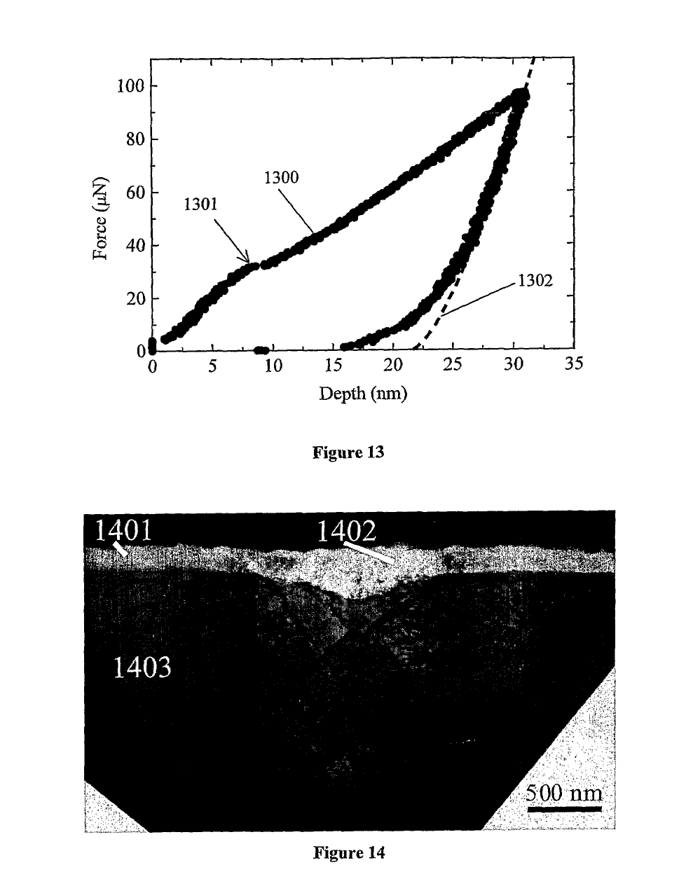

FIG. 13 shows a load-penetration curve 1300 for indentation of Si-I using an indenter with a tip radius of only 77 men. The curve 1300 indicates a maximum penetration depth of ˜30 nm for a load of ˜100 μN. The pop-in event 1301 on loading is characteristic of a phase change from Si-I to the metallic Si-II phase, as described above. The dashed line 1302 is the theoretical unload curve expected for elastic unloading. Ile significant deviation of the measured data 1300 from the theoretical elastic unloading curve 1302 indicates that a further phase transformation occurs during unloading after nanoscale indentation. This suggests the formation of Si-III/Si-XII for slow unloading, or amorphous Si for fast unloading, as described above for indentation with micron-sized indenters

### Annealing Processes

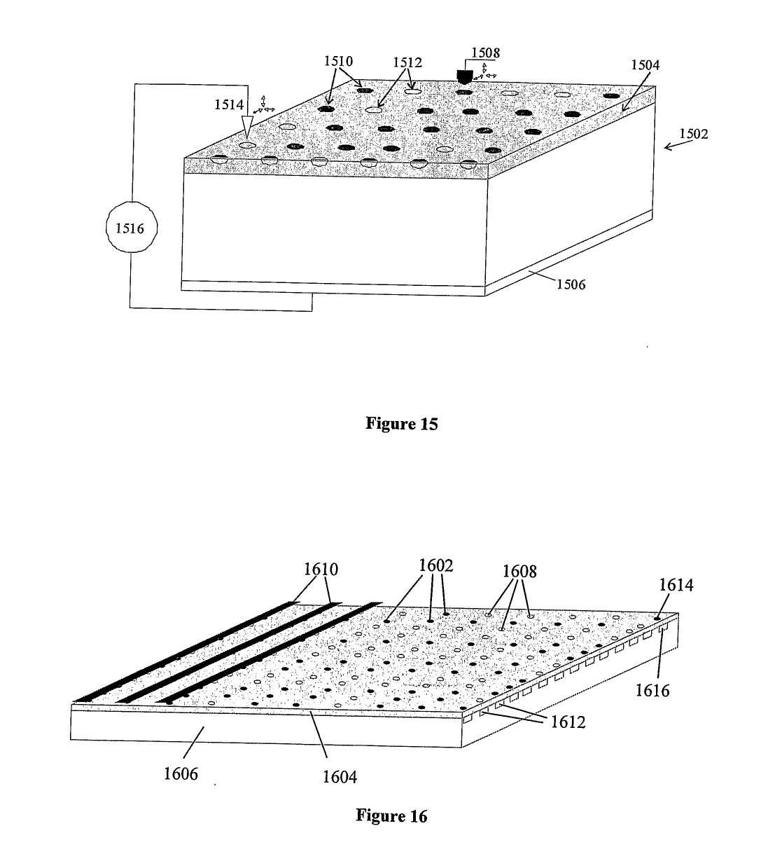

Heating the region of phase transformed Si-XII/III material in the relaxed amorphous Si sample to temperatures above 200° C. and up to 450° C. for 30 minutes causes the Si-XII/III phase to undergo a further transformation to the Si-I state. Significantly, amorphous Si that is within the transformed region containing Si-XII/III is also transformed to Si-I. However, a-Si that surrounds the indented region (i.e., a-Si that has not undergone any phase transformation on indentation) does not undergo a phase transformation to Si-I when heated to temperatures up to 450° C. for 30 minutes. FIG. 15 shows an XTEM image of an indent in a thin film of relaxed a-Si 1401 on c-Si 1403. After indentation, XTEM analysis (not shown) confirmed that the indented portion of the a-Si thin film 1401 had been transformed to the Si-XII/III phases. The sample was then heated to 450° C. for 5 mins, which caused the Si-XII/III phases to transform to the Si-I phase 1402, as shown by the bright surface regions 1402 in the XTEM image of FIG. 14. The surrounding (unindented) a-Si in the thin film 1401 remains untransformed.

### The Preferred Embodiments

The above results demonstrate that, surprisingly, relaxed a-Si can be transformed to crystalline phases by indentation. Thus, analogous to Si-I, relaxed a-Si undergoes a transformation to the Si-II phase on loading, and undergoes further transformation on unloading, forming either Si-XII and Si-III, or a-Si, depending on the unloading rate, This means that it is possible to go from a crystalline structure to an amorphous structure and back again by mechanically deforming Si (either Si-I or a-Si) in a controlled manner, as shown in FIG. 12. Hence it is possible to start with relaxed a-Si and, using indentation with a slow unloading rate, finish with Si-XII/Si-III, or using a fast unloading rate, return to a-Si.

Because the electrical conductivity of silicon depends on whether the silicon is crystalline or amorphous, it is therefore possible to controllably (and reproducibly) generate regions of (conducting) crystalline silicon or (insulating) amorphous silicon by controlling the rate of unloading during indentation. Such regions can be repeatedly transformed from either conducting state into the other conducting state by re-indenting the previously indented regions.

The ability to controllably and repeatedly transform localised regions between an amorphous phase and one or more crystalline phases by applying and removing pressure can be used to provide a variety of useful structures and devices. In particular, a rectangular or other shaped array of such regions can be used to provide the memory cells of an array-based non-volatile electronic memory device, wherein bits of stored information are represented by the electrical conductivity of each region. Because the phase transformations have been observed to occur during indentation of nanoscale regions, ultra-high-density memory storage devices can be provided by ibis technology.

For example, the following write and erase actions are possible:
1. Write Load relaxed a-Si and slow unload to form Si-XII/Si-III; and
2. Erase Load the Si-XII/Si-III and fast unload to form a-Si.

### MEMS—Integrated Read/Write/Erase Probe

FIG. 15 is a schematic diagram of such a memory device in which a piece of silicon 1502 has a surface layer 1504 of relaxed amorphous silicon. As described above, this layer 1504 can be created by first forming an unrelaxed amorphous layer by either deposition or ion implantation, and then relaxing the amorphous layer using a low temperature annealing step (e.g., 450° C. for 30 minutes under flowing nitrogen). A metallic backside contact 1506 provides an electrical contact to the back of the wafer 1502. An indenting probe 1508 is used to ‘write’ bits of binary data by creating crystalline regions 1510 consisting of Si-III/Si-XII crystalline phases at selected locations on the relaxed amorphous silicon layer 1504. By controlling the unloading rate of the indenting probe 1508 (e.g., by ensuring that the unloading rate is less than 3 mN s⁻¹ for a 4.2 μm radius spherical indenter tip), the indented regions are transformed from the relatively electrically insulating amorphous phase to a relatively electrically conductive crystalline phase during slow unloading. In-situ electrical measurements during indentation of silicon suggest that the resistivity of the transformed crystalline and amorphous phases produced by indentation differ by around an order of magnitude.

A conducting probe 1514 electrically connected to the back contact 1506 of the wafer 1502 via a power source 1516 can be moved across the surface of the wafer 1502 using a suitable translation means (not shown), such as a micro-electro-mechanical actuator based on an electrostatic comb drive, a magnetic actuator, piezoelectric members and/or a shape-memory alloy such as TiN, for example. When the probe 1514 is positioned over the location of a crystalline (transformed) region 1510, electrical current generated by the current source 1516 can easily flow through the conductive crystalline region 1510 to the underlying silicon 1502, particularly if the thickness of the transformed conductive crystalline region 1510 is at least comparable to, and preferably equal to or greater than, the thickness of the amorphous layer 1504.

Conversely, when the probe 1514 is positioned over an amorphous (untransformed or re-transformed by fast unloading) region 1512, electric current cannot easily flow through the relatively insulating amorphous region 1512. Thus by detecting differences in the electrical conductivity of the surface layer 1504, the state of the region below the probe 1514 can be determined in a manner analogous to that used in a scanning tunnelling microscope (STM) or an atomic force microscope (AFM). Moreover, by representing one binary state as an insulating amorphous region 1512 and the complementary binary state as a crystalline conductive region 1510, binary data can be stored by controlling the spatial distributions of the amorphous regions 1512 and the crystalline regions 1510 within a predetermined distribution of sites (or memory cells), such as a regular array, as shown.

In an alternative embodiment, the thickness and therefore resistance of each transformed conductive region is determined by controlling the maximum pressure applied to the indenter tip. By selecting a desired resistance value from a fixed number of possible resistance values, each region can be used for multi-bit storage. For example, by controlling the pressure applied to a single nanoscale region to select the resistance of that region from eight possible resistance values, three bits of information are effectively stored in that region.

In one embodiment, a single conducting probe 1514 is moved across the surface layer 1504, using a micro-electro-mechanical actuator. In an alternative embodiment, a linear or rectangular or other shaped array of conducting probes or circuits (not shown) is used so that many regions can be read simultaneously. If the number of conducting probes in the probe array is the same as the number of memory cells, then the conducting probe array is fixed relative to the silicon wafer 1502. Alternatively, if the dimensions of the conducting probe array are smaller than those of the cell array, then the conducting probe array is mounted to an actuator assembly and is moved relative to the surface of the wafer 1502 so that all of the memory cells can be read. The probes need to be cleaned before use and kept in a relatively dust-free environment.

In order to erase the contents of the memory cells, the transformed (crystalline) regions 1510 are re-transformed back into an amorphous state by re-indenting with the indenter 1508 followed by rapid unloading, as shown in FIG. 12. Thus, by re-loading a memory cell containing Si-XII/Si-III, the cell can be transformed to the intermediate phase Si-II. Fast unloading from this phase then results in a further phase transformation back to the a-Si phase.

In one embodiment, the memory device is a read-write device, and the indenter 508 is an integral part of the memory device. The indenter 1508 and the conducting probe 1514 can be mounted on the same actuator assembly.

Alternatively, a single conducting probe/indenter harder than Si-I can provide the functions of the indenter 1508 and the conducting probe 1514. Because the contacting area of the indenting probe 1508 is of the order of 10 nm in diameter, an indenting force in the μN range is sufficient to provide the ˜11 GPa required to transform amorphous silicon into a crystalline phase.

Alternatively, if the memory device is a read-only device, the indenter 1508 is only needed to store the binary (or multi-bit) data (for example, during manufacture) and does not have to be part of the memory device. An external indenter can be used in this case.

The lateral dimensions of the memory cells can be as small as desired, subject to the physical constraints of the indenter 1508 and the conducting probe 1514 and electrical crosstalk between cells. Since AFM (and STM) tips of 10 nanometers are routinely used, the dimensions of the cells may be limited by the physical dimensions of the indenter 1508, rather than those of the conducting probe 1514. Accordingly, nanometer-scale memory cells can be produced when the tip of the indenter 1508 is also of nanometer scale For example, FIG. 13 shows a load-unload curve 1300 for indentation of Si-I using an indenter with a tip radius of only 77 nm.

### Solid State Device—ROM

In an alternative embodiment, conductive crystalline regions 1602 are formed at selected sites in a layer 1604 of relaxed amorphous silicon over an insulating substrate 1606 (e.g., sapphire), as shown in FIG. 16. Thus the surface of the relaxed amorphous layer 1604 can be considered to incorporate a rectangular array of sites 1602, 1608, comprising conductive sites 1602 formed by indentation with slow release, and insulating sites 1608 where no indentation has been performed. A set of elongated parallel conductors 1610 is then formed over all of the sites 1602, 1608. Although only three parallel conductors 1610 are shown in FIG. 16 for clarity, it will be appreciated that in practice additional conductors similar to the conductors 1610 would be formed over all of the sites 1602, 1608. Buried beneath the layer 1604 of relaxed amorphous silicon lies another set of elongated parallel conductors 1612, perpendicular to the uppermost conductors 1608, and over which all of the sites 1602, 1608 have been formed. One of the sets of conductors, for example the upper conductors 1610, are used as bitlines, and are hereinafter referred to as bitlines 1610. The other set of conductive stripes, i.e., the buried conductors 1612, are used as wordlines, and are hereinafter referred to as wordlines 1612.

Accordingly, a selected memory cell 1614 can be addressed by applying a bias to the corresponding wordline 1616 and measuring the current flowing along the corresponding bitline overlaying the site 1614 and not shown in FIG. 16 for clarity. This current will be appreciably larger (typically more than an order of magnitude) if the region defining the selected cell 1614 has been transformed into crystalline silicon than if the cell has not been transformed and remains amorphous.

The structure of FIG. 16 can be produced by the following process:
(i) Select a silicon-on-sapphire wafer having a Si surface layer of relatively low resistivity (<0.01 Ω-cm). Use ion implantation and lithography (i.e., masked ion implantation) to amorphize a series of parallel elongated strips or channels of the Si surface layer down to the underlying sapphire to create insulating channels, with the remaining crystalline silicon subsequently defining the conductive buried 1612 strips at step (ii) below;
(ii) remove the implantation mask and then perform a second, shallower implantation to completely amorphize a surface portion of the silicon layer and thereby define the amorphous surface layer 1604; this also amorphizes the surface of each conductive strip defined in step (i), thereby forming the buried conductive channels 1612 that are used as wordlines;
(iii) anneal the wafer at 450° C. for 30 minutes under flowing nitrogen to relax the a-Si surface layer 1604;
(iv) selected localised regions 1602 are then indented to form localised conductive regions 1602 and thereby store data in the amorphous 1604 layer overlaying the wordlines 1612,
(v) annealing of the wafer may be undertaken to transform the indented conducting regions to Si-I which is expected to have a higher conductivity; and
(vi) lithography and metal deposition are then used to form the conductive bitlines 1610 over the localised crystalline regions 1602 and the remaining amorphous regions 1608.

It will be apparent that in order to most easily distinguish the electrical conductivity of the transformed and untransformed regions, it is preferable that the vertical thickness or depth of the transformed conductive crystalline region is equal to or greater than the thickness of the amorphous layer 1604. This is dependent on the physical dimensions of the indenter and the force applied during indentation, and hence the thickness of the layers is determined accordingly.

As described above, a single bit of information can be written by transforming an electrically insulating region into an electrically conducting region. The bit is read by measuring the electrical conductivity of the region, and in the embodiment of FIG. 15, the bit can be erased by retransforming the conducting region into an insulating region, in this case by re-loading the transformed region with ˜11 GPa of pressure and unloading rapidly. The embodiment in FIG. 16 is a read-only device and can be read by addressing each cell using the arrangement of wordlines 1612 and bitlines 1610 as shown.

In yet a further alternative embodiment, charge is stored in selected cells of an array of crystalline Si regions made, as above, by indentation. This device operates in an analogous way to a MOS structure with the active crystalline cell encapsulated (above and below) by an insulating material such as amorphous silicon or SiO₂, for example.

In yet a further embodiment, a memory array device is based on conductivity differences between isolated regions of electrically insulating amorphous silicon in a layer of electrically conducting crystalline silicon. The insulating amorphous silicon regions are initially formed in a layer of crystalline Si-I by indentation using rapid unloading. Once formed, an amorphous region can be re-transformed by re-indenting using slow unloading to form one or more conductive crystalline phases.

Although the memory devices described above are based on transformations between an amorphous phase and one or more crystalline phases, it will be apparent that any phase transformation that can be induced by pressure to change the electrical conductivity of the cell material can be alternatively used, and that the material undergoing the phase transformation need not be silicon but can be any substance or material that is capable of undergoing such a transformation. The substance may be elemental or a compound substance.

In the memory devices described herein, the physical dimensions of the memory cells formed by indentation depend upon the size of the indenter tip. Although the nanometer-scale memory cells described above provide memory devices having extremely high storage density, millimeter-scale memory cells can be used to provide memory devices having relatively low storage densities, but which can be manufactured at a much lower cost. Such devices are desirable for use in low cost applications that do not necessarily require storage of large amounts of information, such as smart cards or train tickets, for example.

Although preferred embodiments of the present invention have been described above in terms of memory devices, it will be apparent that the ability to change one or more electrical and/or physical properties of one or more regions of a substance by applying and removing pressure to those regions is not limited to application in memory devices, but may be exploited in a wide variety of applications. In particular, the ability to controllably and repeatedly change at least one electrical and/or physical property from a first value to a second value and back to the first value can be particularly advantageous. However, the processes described herein can also be applied to a substance only during manufacture to produce a fixed structure including one or more localised regions having one or more properties (which may or may not include an electrical property) that differ from those of the substance surrounding those regions. Such an arrangement is referred to herein as a structured material. For example, the structured material may be an array of (possibly nanoscale) regions of at least one first phase of a substance surrounded by at least one second phase of the same substance, such as an array of crystalline regions surrounded by an amorphous phase, or vice versa. As the electrical and physical properties of the substance may differ between the various phases, it is envisaged that such a structured material may be useful in a wide variety of applications, including sensors.

Accordingly, although the preferred embodiments have been described above in terms of phase transformations, it will be apparent that any property change that can result from applying pressure to and removing pressure from one or more regions of a substance can be used to form a structured material or to store information. For example, alternative embodiments can be used to produce a structured material having one value for a particular property (which need not be an electrical property), with localised regions having one or more different values for that property. The localised regions may be on a nanoscale. Accordingly, the substance can be any substance that is capable of undergoing such a property change by the application and removal of pressure. The substance may be an element or a compound.

Many modifications will be apparent to those skilled in the art without departing from the scope of the present invention as herein described with reference to the accompanying drawings.

1. An information storage process, including:
applying pressure to one or more regions of a substance; and
storing information in said one or more regions by removing said pressure.

2. A process as claimed in claim 1, wherein said one or more regions provide one or more memory cells for a memory device.

3. A process as claimed in claim 2, wherein dimensions of each of said memory cells are on a nanometer scale.

4. A process as claimed in claim 1, including measuring a property of said one or more regions to determine the information stored in said one or more regions.

5. A process as claimed in claim 4, wherein said property includes conductivity or resistance.

6. A process as claimed in claim 1, wherein the applying and removing of pressure includes transforming said one or more regions from at least one first phase to at least one second phase.

7. A process as claimed in claim 6, wherein said at least one first phase includes an amorphous phase, and said at least one second phase includes at least one crystalline phase.

8. A process as claimed in claim 7, wherein said amorphous phase is a relaxed amorphous phase.

9. A process as claimed in claim 8, wherein said substance is substantially silicon.

10. A process as claimed in claim 6, including heating said one or more regions to induce further phase change in said one or more regions.

11. A process as claimed in claim 10, wherein said heating transforms said at least one crystalline phase to a more conductive crystalline phase.

12. A process as claimed in claim 1, wherein the applying and removing of pressure includes controlling at least one of the applying and removing of pressure to determine the information stored in said one or more regions.

13. A process as claimed in claim 1, wherein the step of storing information includes controlling a rate of said removing of said pressure to determine the information stored in said one or more regions.

14. A process as claimed in claim 1, including selecting the pressure applied to each of said one or more regions to determine the information stored in said one or more regions.

15. A process as claimed in claim 14, wherein the pressure is selected from a plurality of predetermined pressures to provide multi-bit information storage in each of said one or more regions.

16. A process as claimed in claim 1, wherein the applying and removing of pressure changes the electrical conductivity of said one or more regions from a first electrical conductivity to a second electrical conductivity, and the process further includes applying pressure to and removing pressure from said one or more regions to change the electrical conductivity of said one or more regions from said second electrical conductivity to a third electrical conductivity.

17. A process as claimed in claim 16, wherein said third electrical conductivity is substantially equal to said first electrical conductivity.

18.-34. (canceled)

35. A memory device, including a plurality of memory cells created by applying pressure to respective regions of a substance and changing the electrical conductivity of said regions by removing said pressure from said regions to provide said plurality of memory cells.

36. A memory device as claimed in claim 35, wherein dimensions of said memory cells are on a nanometer scale.

37.-50. (canceled)

51. A structured material, including one or more substantially crystalline regions in a layer of relaxed amorphous silicon.
